(19) United States
(12) Patent Application Publication
(10) Pub. No.: US 2024/0072799 A1
(43) Pub. Date: Feb. 29, 2024

(54) USER INTERFACE CAPACITIVE TOUCH CONTROLS WITH LED ILLUMINATION

(71) Applicant: Spectrum Brands, Inc., MIddleton, WI (US)

(72) Inventors: Karl W. Marschke, Fitchburg, WI (US); Brian L. Vodvarka, Grand Marsh, WI (US); Grant T. Oberhauser, Madison, WI (US); Charles Quinn, Sun Prairie, WI (US); Kroy E. Nernberger, Madison, WI (US); Matthew J. Quock, Middleton, WI (US); Steven J. Buth, Deforest, WI (US); Michael S. Rubrich, Sun Prairie, WI (US); David W. Everett, JR., Verona, WI (US)

(21) Appl. No.: 18/271,722

(22) PCT Filed: Jan. 12, 2022
(86) PCT No.: PCT/US2022/012097

§ 371 Date: Jul. 11, 2023

Related U.S. Application Data
(60) Provisional application No. 63/136,314, filed on Jan. 12, 2021.

(51) Int. Cl. H03K 17/96; A47J 36/32; A47J 43/07; F24C 7/08

(52) U.S. Cl. CPC H03K 17/9622; A47J 36/32; A47J 43/07; F24C 7/086; H03K 2217/96015; H03K 2217/96066; H03K 2217/960785

(57) ABSTRACT

A multi-layer touchscreen assembly for an appliance includes a panel including an outer touchscreen surface, an opaque layer positioned below the touchscreen surface and having at least one transparent area therein defining lighting of at least one visual touch control region, a printed circuit board positioned below the opaque layer, the printed circuit board including a plurality of light-emitting diodes proximate one or more corresponding capacitive touch sensors of a first visual touch control region of the one or more visual touch control regions, and the one or more capacitive touch sensors configured to provide a visual indication of a control aspect of the appliance according to a user's touch input. The assembly also includes at least one diffusion portion operatively positioned between the opaque layer at a transparent area thereof and the printed circuit board at the first visual touch control region.

### CROSS REFERENCE TO RELATED APPLICATIONS

This application claims priority to and the benefit of U.S. Provisional Patent Application No. 63/136,314, filed Jan. 12, 2021, the entire contents of which is incorporated herein by reference in its entirety.

### BACKGROUND

Food preparation appliances such as blenders and food processors are commonly used to process foods, such as by chopping, crushing, cutting, liquefying, blending, mixing, etc. Such appliances typically have a container, such as a jar, in which the food is loaded for processing. The jar has one or more rotatable blades disposed within the jar. When the jar is set on a base that houses a drive motor, the drive motor is drivingly connected to the one or more rotatable blades in the jar. A lid is typically placed on the top of the jar to close the jar during operation of the appliance. Such appliances typically have mechanical or electronic controls. One type of electronic controls is touch controls. Touch controls offer a clean, flat touchscreen appearance to an appliance control panel, and are often desirable for a variety of reasons.

### SUMMARY

The present invention is directed to a multi-layer capacitive touch configuration for use with an appliance that provides reduced thickness and simpler construction by providing touch controls and visual indications of control aspects on a single side of a single printed circuit board.

According to a first aspect of the present disclosure, a multi-layer touchscreen assembly for an appliance is disclosed. According to the first aspect, the assembly includes a panel including an outer touchscreen surface. The assembly also includes an opaque layer positioned below the touchscreen surface and having at least one transparent area therein defining lighting of at least one visual touch control region. The assembly also includes a printed circuit board positioned below the opaque layer, the printed circuit board including a plurality of light-emitting diodes proximate one or more corresponding capacitive touch sensors of a first visual touch control region of the one or more visual touch control regions, and the one or more capacitive touch sensors configured to provide a visual indication of a control aspect of the appliance according to a user's touch input. The assembly also includes at least one diffusion portion operatively positioned between the opaque layer at a transparent area thereof and the printed circuit board at the first visual touch control region.

According to a second aspect, an appliance is disclosed. According to the second aspect, the appliance includes an operative component that is controllable according to at least a controllable aspect. The appliance also includes a multi-layer touchscreen assembly operatively connected to the operative component. According to the second aspect, the touchscreen assembly includes a panel including an outer touchscreen surface. The touchscreen assembly also includes an opaque layer positioned below the touchscreen surface and having at least one transparent area therein defining lighting of at least one visual touch control region. The touchscreen assembly also includes a printed circuit board positioned below the opaque layer, the printed circuit board including a plurality of light-emitting diodes proximate one or more corresponding capacitive touch sensors of a first visual touch control region of the one or more visual touch control regions, and the one or more capacitive touch sensors configured to provide a visual indication of the control aspect of the appliance according to a user's touch input. The touchscreen assembly also includes at least one diffusion portion operatively positioned between the opaque layer at a transparent area thereof and the printed circuit board at the first visual touch control region.

According to a third aspect, a method of making a touchscreen assembly for use in an appliance is disclosed. According to the third aspect, the method includes providing a minted circuit board including a plurality of light-emitting diodes proximate one or more corresponding capacitive touch sensors of a first visual touch control region, the capacitive touch sensors configured to selectively control the appliance according to a user's touch input. The method also includes providing a diffusion holder holding at least one diffusion portion located above the first visual touch control region of the printed circuit board. The method also includes providing an opaque layer having at least a transparent area above the diffusion holder and diffusion portion. The method also includes providing a touchscreen surface above the opaque layer.

### BRIEF DESCRIPTION OF THE DRAWINGS

The present invention will be further explained with reference to the appended Figures, wherein like structure is referred to by like numerals throughout the several views, and wherein:

FIG. 1 is a perspective view of a blender equipped with touchscreen controls, an example of an appliance according to various embodiments.

FIG. 2 is an exploded view of the components of the blender of FIG. 1, according to various embodiments.

FIG. 3 is a close-up view of the touchscreen assembly, according to various embodiments.

FIG. 4A is an exploded view of the touchscreen assembly of FIG. 3, showing various components of the touchscreen assembly according to various embodiments.

FIG. 4B is reverse view of a diffusion holder of the touchscreen assembly of FIG. 3, according to various embodiments.

FIG. 4C is a representative cross-sectional view of various components of the touchscreen assembly of FIG. 3, according to various embodiments.

FIG. 5 is a front view of a circuit board for use with the touchscreen assembly of FIGS. 3 and 4, according to various embodiments.

FIG. 6 is a rear view of the circuit board of FIG. 5, according to various embodiments.

FIGS. 7A-7C show a user interacting with the touchscreen assembly of FIG. 3 in order to control the appliance of FIG. 1, according to various embodiments.

### DETAILED DESCRIPTION

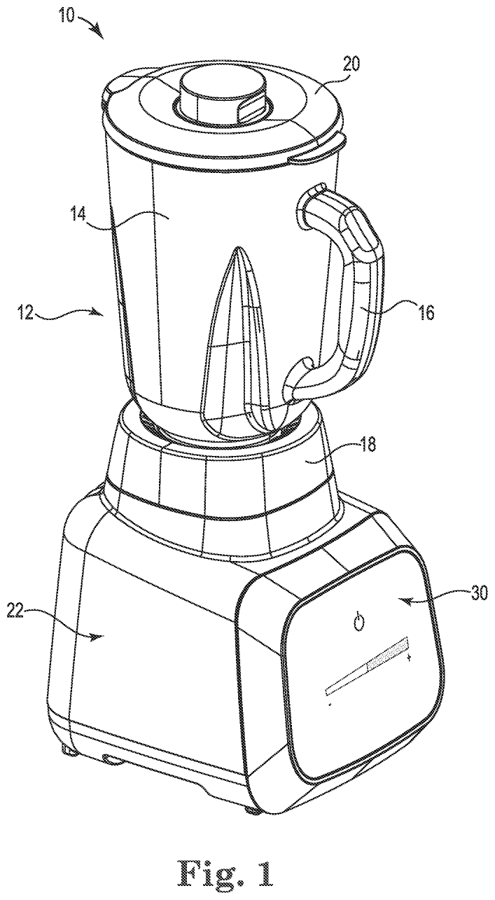

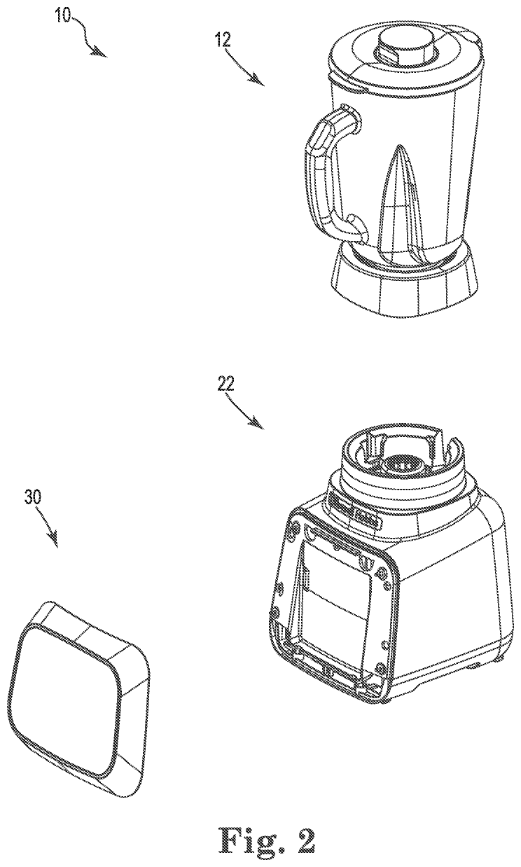

With reference to FIGS. 1 and 2, a blender 10 is shown. The blender 10 is an example of an appliance contemplated herein, but the present disclosure is not limited to any particular type of appliance and the blender 10 is used for illustrative purposes only. The blender 10 is composed of a container assembly 12, a base unit 22, and a control unit/touchscreen assembly 30 (referred to collectively herein as control unit 30). The container assembly 12 includes ajar 14 with a handle portion 16 attached thereto and a cover 20 attached to an upper portion of the jar 14. The container assembly 12 also includes a mounting collar 18 that is configured to interface with a complementary portion of the base unit 22 such that the container assembly 12 can be grasped by a user by the handle 16 and selectively lifted off the base unit 22, such as for cleaning, emptying, filling, and the like, while seating securely to the base unit 22 for blending operation when the container assembly 12 is sitting thereon.

The base unit 22 preferably comprises various electrical and operative components, including an electric motor (not shown) and other operative features that allow a mixing blade (not shown) to selectively rotate to mix a food and/or beverage product within the jar 14 of the container assembly 12. As shown in FIG. 1, also attached to the base unit 22 is a control unit 30. The base unit 22 can optionally include the control unit 30 as a single combined unit.

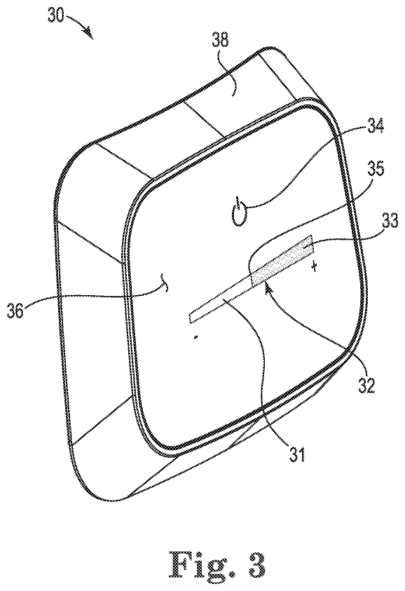

With reference now to FIG. 3, the control unit 30 of the blender 10 appliance is shown removed from other components of the blender 10 and in greater detail. The control unit 30 includes a touchscreen surface 36 surrounded at its exposed periphery by a bezel 38. The touchscreen surface 36 preferably includes one or more touch-based controls at various locations, including a power control 34, and a touch slider control, for preferably continuously adjusting motor speed, shown at 32. Motor speed control operated by the slider control 32 can be digital and in steps or can be analog and continuously adjustable. Additional and/or alternative controls are also contemplated, including function selections, parameter adjustments, and the like. The slider control 32, an example of a visual touch control region, as shown includes a lighted portion 31, and darkened (not currently lighted or alternatively less lighted) portion 33 separated by an electronically movable level line 35 that moves according to various light emitting diodes being in the on or off positions.

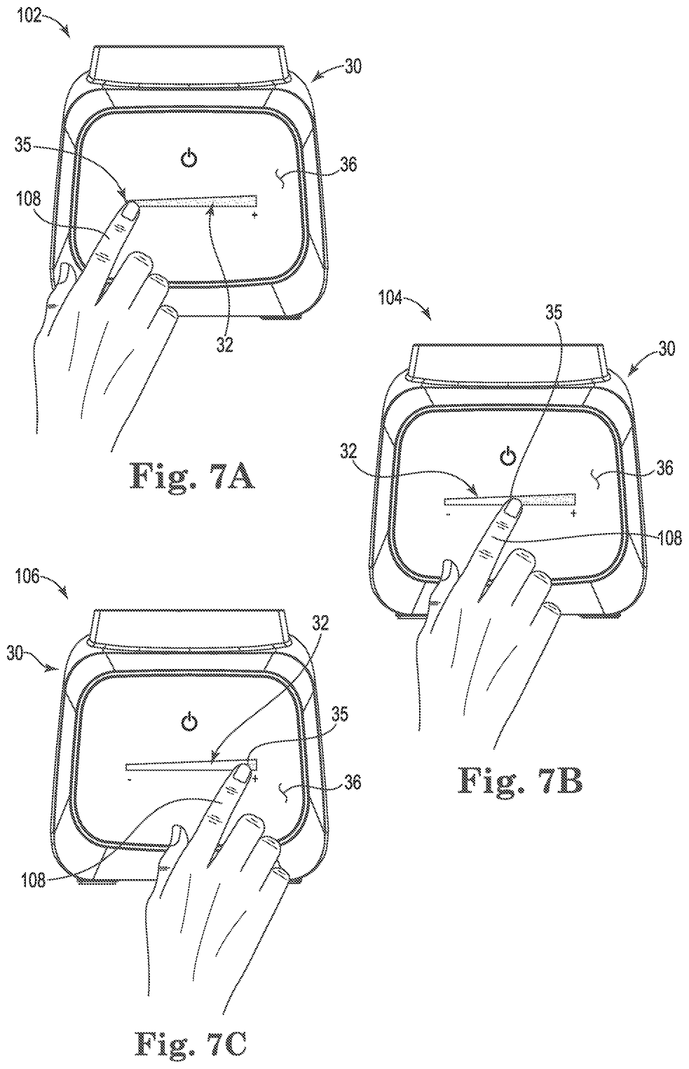

As described herein, the movable level line 35, which delineates the lighted and darkened portions 31, 33 of the slider control 32, preferably dynamically tracks a user's hand or finger as the user selectively touches and operates the blender 10 via the touchscreen surface 36 of the control unit 30. Thus, the slider control 32 provides a visual indication of a control aspect (e.g., motor speed) that includes the visual and movable level line 35. In the example shown in FIG. 3, the example visual touch control region shown as the slider control 32 is a motor speed level controller, with a tapered trapezoidal shape that narrows at a first end (indicating a minimum speed setting or level −) and widens at a second end (indicating a maximum speed setting or level +). Touch controls of the touchscreen surface 36 of the control unit 30 can operate an electric motor, including turning the motor on and off using the power control 34. The touch controls, in particular the slider control 32, can operate as a slider such that a smooth and intuitive motor speed level can be set by a user by sliding the hand along the touchscreen surface 36 until a desired motor speed or other setting is achieved. See also FIGS. 7A-7C below for example user touch-based operation of the control unit 30.

Various existing touchscreen control arrangements have drawbacks that stem from certain physical limitations and trade-offs. One type of touchscreen technology is capacitive touch technology. Some existing touchscreen implementations utilize one or more capacitive touch sensing springs to at least partially reduce an effective distance between a touchscreen surface and a capacitive touch sensor. Input connections via springs can sense the change in capacitance provided by the user when close to the end of the spring. Yet further existing arrangements utilize indirect or angled lighting that is arranged at an angle such as 90 degrees to the touchscreen face, leading to more complexity and cost, among other drawbacks.

As such, a need exists for a capacitive touchscreen control setup with one or more visual touch control regions, and that minimizes feature thickness between a user's hand (or other interface device, such as a stylus, glove, and the like) and the operative touchscreen pads or sensors, while also offering an even, diffused lighting setup that provides improved aesthetics in addition to functionality in a single printed circuit board (PCB) construction.

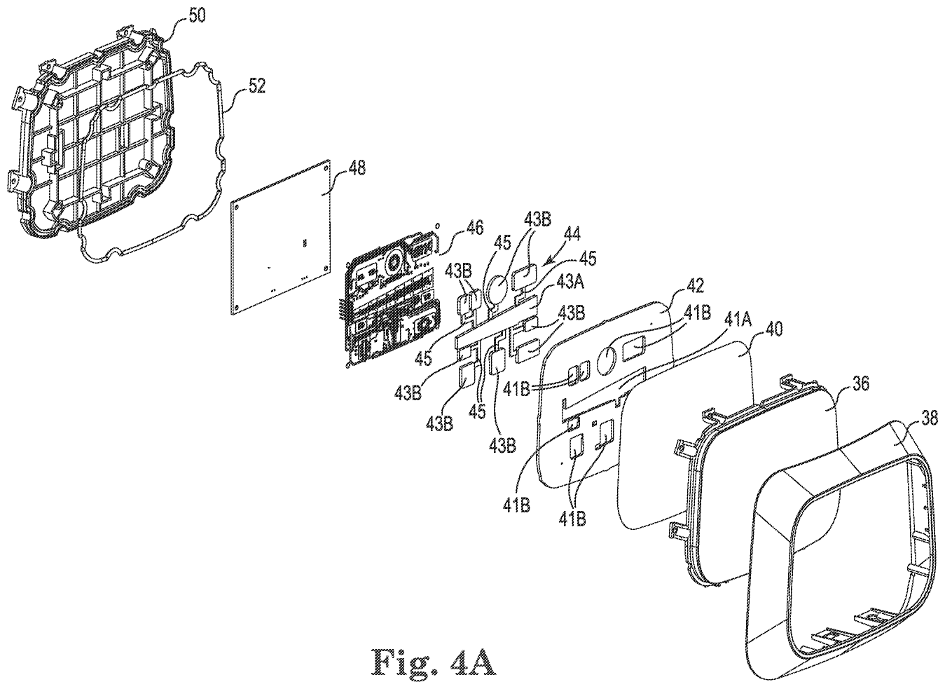

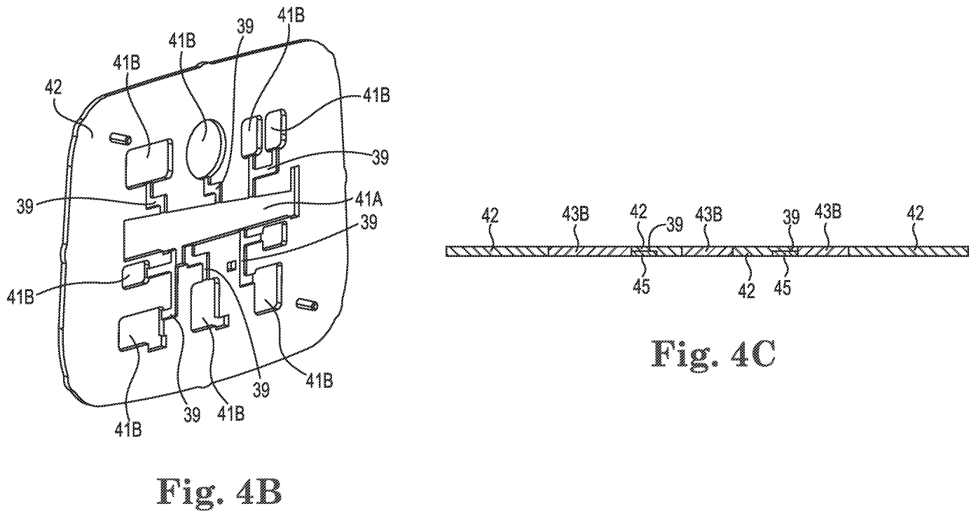

FIG. 4A-4C show various aspects of the control unit 30. In particular, the control unit 30 is composed as a multi-layer capacitive touch configuration for use with the blender 10, and the control unit 30 provides reduced operative thickness and simpler construction by providing touch controls and lighting on a single PCB 46. More specifically, disclosed herein is a user interface at the control unit 30 with capacitive controls and visual indicating light emitting diode (LED) illumination having an optimized assembly using a single-sided PCB within the control unit 30. Embodiments include integrating the visual indicating LEDs inside the touch sensitive slider control 32 portion having multiple capacitive touch sensors at visual touch control regions. Disclosed embodiments use one or more touch pads or sensors mounted to the PCB 46 directly as the input sensor for the user's finger. Touch pads or sensors (which can be used interchangeably herein) can also refer to any type of touch sensor, mechanism, or feature that enables a detection and/or interpretation of a capacitive touch input, such as a wire or the like.

Overall, a touchscreen assembly of the control unit 30 has a “stack” of layered and interfaced parts, one embodiment of which is shown in the exploded view of FIG. 4A. As shown, from outermost or innermost, the stack of the control unit comprises the bezel 38, the touchscreen surface 36 and front panel, an opaque, light-blocking (e.g., Mylar) layer 40 positioned below the touchscreen surface 36 and defining lighted regions, a diffusion holder 42, a diffusion layer 44, a PCB 46, a PCB mounting surface 48, and a mounting substrate 50 with a gasket seal 52 positioned between the substrate 50 and the bezel 38. As noted below, it is also contemplated that the diffusion holder 42 and diffusion layer 44 can be assembled and fitted together preferably in a flush arrangement in any order relative to the other.

The touchscreen surface 36 is embodied in a front panel (also shown at 36) that is preferably composed of a transparent plastic or other material that allows the light passing through defined areas or zones of the opaque layer 40 to be viewed by the user. The user touches the touchscreen surface 36 to make selections with capacitive touch controls through control unit 30. The opaque layer 40 preferably includes transparent defined areas in the form of removed or preferably transparent portions for text, symbols, etc. for LED light to travel through to the touchscreen surface 36 of the front panel. The opaque layer 40 preferably defines what a user sees during operation of the blender 10. In some embodiments, the opaque layer 40 includes a base transparent layer with an opaque substance (e.g., ink, Mylar, paint, other pigment, etc.) distributed or printed on such that certain areas of the base transparent layer remain transparent and other areas define opaque (non- or partially light transmissive) regions. Various patterns and configurations of transparent vs. opaque regions can for example correspond to the visual touch control regions on the touchscreen surface 36 and/or lights/LED placement on the PCB 46. In alternative embodiments, the opaque layer 40 can have entirely open portions that provide a see-through functionality by selectively removing (or otherwise not providing) a portion of the opaque layer 40 entirely.

The diffusion layer 44 preferably operates as one or more diffusers in a single plane that diffuse the light between the visual indicating (of a control aspect) LEDs of the PCB 46 and the opaque layer 40. The diffusion layer 44 can include one or more lenses and/or diffusers, called diffusion portions 43 herein, that are preferably provided as a single connected unit (see FIG. 4A). The diffusion portions 43 can be operatively positioned between the opaque layer 40 at a transparent area thereof and the PCB at a visual touch control region thereof. The diffusion layer 44 can include a plurality of diffusion portions 43, each corresponding to a different visual touch control region of the control unit 30 and thus position between plural corresponding transparent areas of the opaque layer 40 and additional visual touch control regions of the PCB. The plural diffusion portions 43 are preferably operatively positioned at least partially within shaped openings of a diffusion holder 42 that is also operatively positioned between the opaque layer and the PCB. Preferably, the plural diffusion portions 43 are also connected to one another by connecting runners 45 to position the plural diffusion portions within the shaped openings of the diffusion holder 42 in a similar manner relative to the diffusion holder 42. Preferably, the diffusion holder 42 is of a similar thickness as the plural diffusion portions 43 and the connective runners 45 are thinner than the plural diffusion portions 43 and are positioned with the like thickness groove-like recessed portions 39 of the diffusion holder 42. In various embodiments, one or more of the combination of a transparent area of the opaque layer 40, a diffusion portion 43, and a visual touch control region of the PCB form the touch sensitive slider control 32 that can be of greater width from one end thereof to another end thereof.

The diffusion layer 44 can operate as a generally planar diffusion unit that comprises multiple diffusion portions 43 that relate to separate corresponding LEDs of the PCB 46. For example, the touchscreen surface 36 can be provided with multiple controls and/or lighting portions in discrete locations with corresponding diffusion portions 43 for each control and/or lighting portion.

As shown in FIGS. 4A and 4B, the diffusion holder 42 preferably includes one or more selectively removed, omitted, and/or shaped openings 41 that are configured to receive at least partially transparent, translucent, removed entirely, and/or hold distinct diffusion portions 43 of the diffusion layer 44. As shown in FIG. 4C, an example cross section of an assembled diffusion holder 42 and diffusion layer 44 is shown. As shown, the diffusion holder 42 can operate in combination with the diffusion layer 44 to provide a generally flush unit with multiple discrete diffusion area diffusion layer 44 and holder 42 in a single plane without a need to provide multiple functionally separate diffusion pieces or layers to be held by the diffusion holder 42. Preferably, the shaped openings 41 have outlines that are shaped and sized to fit tightly and correspondingly in a plane with respective diffusion portions 43.

Aspects of capacitive touch can be incorporated into the control unit 30 of the blender 10 in order to have improved light diffusion and evenness would benefit from a thick diffusion layer over one or more touch pads or sensors. However, a thicker light diffusion layer would have the drawback of making capacitive touch control less sensitive and/or precise, leading to compromises on one or both of light diffusion and touch sensitivity. The above configuration can minimize total unit operative thickness and improve capacitive touch performance among other benefits.

With reference in particular to the reverse view of diffusion holder 42 shown in FIG. 4B, and in some preferable embodiments, the diffusion holder 42 can be provided with one or more slot-like recessed portions 39 that are shaped and configured to fit complementarily and interface with the runners 45 of the diffusion layer 44 such that the diffusion holder 42 and diffusion layer 44 are able to be fitted together flush and substantially co-planar for assembly in control unit 30. The cross-sectional view of FIG. 4C shows that the runners 45 and corresponding recessed portions 39 preferably have a thickness that is less than the overall diffusion holder 42 thickness. When the control unit 30 is assembled, the diffusion portions 43 preferably lie at least partially within shaped openings 41 of the diffusion holder 42, and the runners 45 preferably lie at least partially within recessed portions 39.

The diffusion layer 44 is preferably formed of a single unitary construction, and is preferably provided with one or more relatively narrow runners 45 that connect multiple diffusion portions 43A and 43B (collectively 43) of the diffusion layer 44 to one another. For example, a single mold can be used to form the diffusion layer 44 that includes a plurality of diffusion portions 43 connected by runners 45 that would be blocked by the diffusion holder 42 when the blender 10 control unit 30 is assembled. In some examples, a connection runner 45 of the diffusion layer 44 can connect more than one diffusion portion 43 to another diffusion portion 43, such as a slider diffusion portion 43A, which can be sized and shaped to be larger than other diffusion portions 43B according to a surface area occupied by a particular control on the touchscreen surface 36 and the lighting and functionality thereof.

With reference again to FIG. 4C, shown is an example cross section passing through the diffusion holder 42 and three separate diffusion portions 43 along with two runners 45. The runners 45 of the diffusion layer 44 shown positioned in the respective recessed portions 39 of the diffusion holder 42. The recessed portions 39 of the diffusion holder 42 have a depth selected such that the diffusion portions 43 are co-planar at the surfaces with the diffusion holder 42. In other embodiments, the recessed portions 39 are not co-planar at the surfaces with the diffusion holder 42. FIG. 4C also shows a preferred embodiment where diffusion portions 43 are co-planar with both top and bottom sides of the diffusion holder 42. The diffusion portions 43 of the diffusion layer 44 and the diffusion holder 42 accordingly leave little or no gaps therebetween. Lack of space or gaps can improve capacitive touch performance. Using a diffusion holder 42 as shown can improve compactness and also capacitive touch performance as it reduces gaps as a solid body when assembled in the stack for use as a capacitive control unit 30 for blender 10.

The embodiments with reference to FIG. 4A-4C show components of a control stack for a capacitive touch control unit 30 including a diffusion holder 42 having recessed portions 39 on a PCB-facing, underside of the diffusion holder 42. In other embodiments the recessed portions 39 can be formed on an opaque layer 40-facing top side of the diffusion holder 42. In preferred embodiments, assembling the capacitive touch control stack of the control unit 30 is done such that the diffusion layer 44 is attached to the diffusion holder 42 from a direction or side in which the corresponding recessed portions 39 are formed.

With respect to lighting aspects, multiple visual indicating LEDs for a control aspect of PCB 46 can be diffused as groups by each independent diffusion portion 43 corresponding to each visual touch control region. Alternatively, one LED can be diffused by an entire diffusion portion of the diffusion layer 44. In various embodiments, the light produced by a group or array of multiple LEDs is diffused by separate diffusion portions 43 in discrete areas corresponding to separate visual touch control regions of the touchscreen surface 36. In preferable embodiments, a single diffusion portion that diffuses the light of multiple LEDs can provide a unified, even lighting appearance in which it is not readily apparent to an observer than distinct LEDs are producing a combined lighting of the diffusion portion of the diffusion layer 44. In various embodiments herein, the slider control 32 feature of the touchscreen surface 36 controls, such as a visual touch slider control, can include a tapered appearance between minimum and maximum settings as displayed.

When installed within control unit 30 of blender 10, the diffusion layer 44 is preferably held and defined by the complementary diffusion holder 42 that is substantially co-planar with the diffusion portions 43 and diffusion layer 44. The diffusion holder 42 and diffusion layer 44 have substantially the same thickness and can form a combined diffusion layer assembly. The diffusion holder 42 is configured to hold the diffusion layer 44 in place and provides a solid body in between the opaque layer 40 and the PCB 46. Preferably, air gaps and spacing are minimized to improve the touch sensitivity of capacitive touch of the PCB 46 through the various layers above. Generally, a shorter distance and thinner material transfers capacitive touch and a user's input capacitance (and/or changes thereof) more easily and efficiently. Less separation is preferable for capacitive touch operation. Signal strength with a user's finger directly contacting the PCB 46 would provide the greatest capacitive touch sensitivity. A user's finger getting closer to touch pads or sensors can therefore optimally approach the sensitivity of directly touching PCB 46. In one preferable embodiment, a (e.g., silicon) diffusion layer is positioned under the opaque (e.g., Mylar sheet) layer 40, which is positioned behind a (e.g., polycarbonate) touchscreen surface 36, as described herein.

As described above, light diffusion can be achieved using the diffusion layer 44, which can preferably cover entire features of the touchscreen surface 36 and interface (such as the slider control 32) instead of each individual LED of the PCB 46 corresponding to the particular controls. Thus, a smooth, seamless visual effect is achieved while maintaining a thin construction with optimal capacitive touch performance and responsivity. The diffusion layer 44 (and/or diffusion portions 43 thereof) is preferably about 1.5-2 mm thick and made of a light diffusing substance such as silicon. Any runners 45 of the diffusion layer 44 are preferably less than 2 mm thick in various embodiments. The silicon diffusing substance of the diffusion layer 44 can have various levels of tinting pigment or the like in various embodiments. The level of tinting pigment can be selected in accordance with the strength (e.g., light output or brightness) of LEDs used on the PCB 46. In general, more tint tends to reduce “hot spots” on the touchscreen display, but also reduces apparent brightness accordingly. In various embodiments, a semi-transparent polymer can be used for the diffusion layer 44, such as ridged polyethylene pieces positioned in front of the LEDs of the PCB 46.

In some preferable embodiments, surfaces of both the diffusion layer 44 and diffusion holder 42 each contact an adjacent side of the opaque layer 40 when assembled, including in embodiments where the diffusion holder 42 is assembled or provided above or below, or before or after, the diffusion layer 44. In some embodiments, any runners 45 of the diffusion layer 44 do not directly contact the opaque layer 40, but in other embodiments runners 45 do contact the opaque layer 40. In yet further embodiments, the diffusion layer 44 and diffusion holder 42 can be formed as a single unit that is selectively provided with diffusion, transparent, translucent, opaque, or any other suitable optical properties. In even yet further alternative embodiments, the opaque layer 40 is incorporated with the diffusion layer 44 and diffusion holder 42 into a single combined optical diffuser and mask assembly provided above PCB 46 and below touchscreen surface 36. In alternative embodiments, the opaque layer 40 can be omitted entirely or can be positioned separately but below the diffusion layer 44 and diffusion holder 42. In yet further embodiments, the diffusion layer 44 and diffusion holder 42 can be formed as a single unit that is separate from the opaque layer placed above or below.

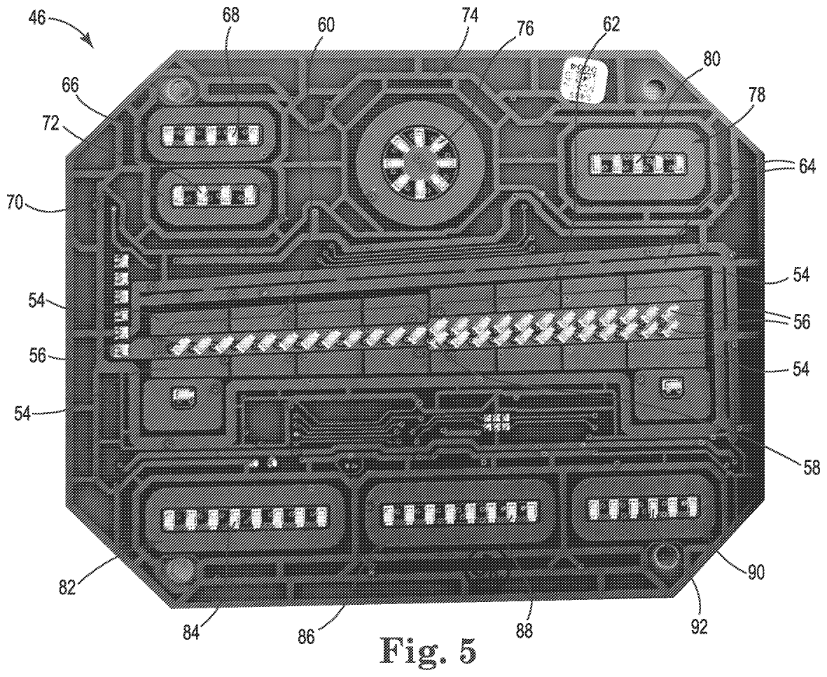

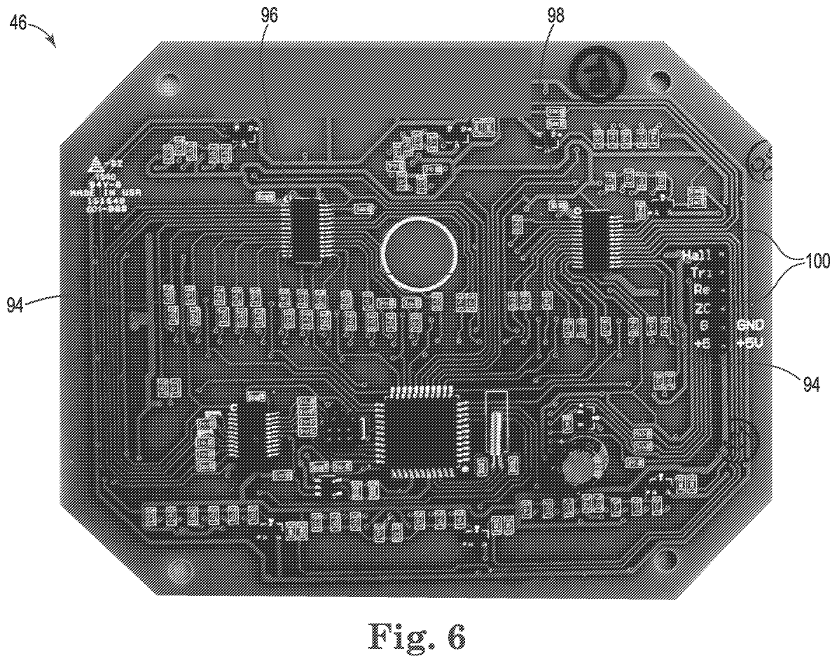

With reference now to FIG. 5 (front) and FIG. 6 (rear), the PCB 46 is shown in greater detail. Operative PCB 46 parts of the slider control 32 are shown with the other layers removed for illustration. The operative PCB 46 parts include slider capacitive touch pads 54 and slider LEDs 56 as shown. Capacitive touch pads as used herein can denote examples of capacitive touch sensors. Touch pads 54 and slider LEDs 56 preferable correspond to visual touch control regions. As shown, both slider capacitive touch pads 54 and slider LEDs 56 are located on the front side of PCB 46. The front side of the PCB 46 shown at FIG. 5 can also include one or more reflective surfaces or components for optimal LED lighting and control aspect visual indicating performance.

The slider LEDs 56 for the motor speed control slider control 32 as shown are arranged in a single row in first portion 60 and in two parallel rows in second portion 62. In various embodiments, the first portion 60 corresponds to a lower setting (speed) portion of the slider control 32 and the second portion 62 corresponds to a higher setting portion of the slider control 32. Also as shown, the touch pads 54 are preferably arranged above and below the LEDs 56 in rows that generally follow and outline or surround of the LEDs 56, which are illustrated as being arranged in a “wedge” like layout shape as shown. In alternative embodiments, the LEDs 56 and by extension the touch pads 54 can be arranged on the front PCB 46 surface in substantially parallel lines or any other suitable arrangement. As shown, a row or multiple rows of the LEDs 56 can be arranged generally in a line, and one end of the line can include a higher density of LEDs 56 per unit length than another end. Upper and lower touch pads 54 can be arranged above and below the line(s) of LEDs 56 such that each location along the line of LEDs 56 is proximate at least two touch pads 54. There can be many different LED density arrangements. In various embodiments, LEDs can be provided in greater numbers than the number of corresponding touch pads 54. In various embodiments, the number of LEDs is twice as many, three times as many, or more, than the corresponding number of touch pads 54.

Also shown in FIG. 5 are other examples of operative touch control units of the PCB 46, which each preferably include touch pad/LED combinations. One such example including touch pad 74 and visual indicating LEDs 76 corresponds to touch-based power control 34 (see FIG. 3). As shown, multiple LEDs 76 are arranged in a circle, although any arrangement or shape is also contemplated. In particular it is noted that multiple LEDs 76 can be positioned and correspond to fewer or even a single touch pad 74. The various touch pad/visual indicating LED combinations can have the same or similar operative features and arrangements as the slider control 32 components.

Additional, optional touch controls can also be included on PCB 46. As shown, a touch pad 78 and LED 80 combination constitutes an additional visual touch control region, and likewise for touch pad/LED combinations shown, including 66/68, 70/72, 82/84, 86/88, and 90/92. Each of the above control/LED combinations can be configured to perform any suitable function on touch control unit 30. Some examples of additional functions can include various mode selections, pulse selections, shortcut settings, ice modes, and the like. Also shown throughout the front side of PCB 46 are traces 64 (e.g., copper or other conductive material) that provide operative interconnections between various operative parts of the PCB 46. Therefore, the PCB 46 design as shown includes all the various operative touch and LED components on one side of the PCB 46. Preferably, the various touch and visual indicating LED components are grouped in various visual touch control regions associated with various sliders and/or buttons of the control unit 30. As shown, the present embodiments are configured to have corresponding LEDs and touch pads located directly adjacent to one another (e.g., 54 and 56, etc.).

In existing configurations that utilize springs for capacitive touch sensing, the springs are used as the sensor pads for electrical and capacitive signals. In preferable embodiments of the present disclosure, electrical traces are instead employed on a PCB 46 surface to detect changes and/or levels of capacitance effected by a user hand or other input. The PCB 46 layout and logic/control configuration allow for the LEDs to be placed in close proximity to the capacitive touch sensors of the PCB 46, among other benefits. In various embodiments, the PCB 46 contains a material such as copper that is utilized itself for the touch pad function with the LEDs inside the touch pads (and therefore surrounded by the copper). In present embodiments, the PCB 46 is positioned close enough to the outer layer the user touches such that the addition of springs was not needed and the structure is simplified accordingly.

This single-side arrangement on the PCB 46 optimizes the manufacturing time as the front side contains both the touch sensors and the visual indicating LEDs. Although the LED and touch operative components are located on one side of the PCB 46 only, the PCB 46 can be a two-sided board. In regard to the traces 64 and the capacitive input touch pads (e.g., 54), the pads are preferably integrated with hole(s) only and not the mounting nodes and traces 64. This preferably maximizes the capacitive surface and allows a relatively close distance to the touch surface which is also beneficial in adjusting capacitive touch and/or proximity detection sensitivity. This configuration also allows a tightly-spaced touch slider design that functions much like a mobile phone. This is in contrast to existing spring-based configurations, which require greater spacing and illumination is often blocked by the springs. In some embodiments a greater density of LEDs is positioned proximate a wider portion of the slider control 32 feature. In such cases the slider control 32 utilizes variable LED lighting density, and the diffusion layer 44 preferably provides a smooth, seamless appearance as LED lighting density and arrangements change based on positioning along the slider control 32. As shown, touch pads are positioned above and below corresponding LEDs for respective visual touch control regions.

By positioning the various touch pads on multiple sides of the LEDs, improved and ergonomic touch zones are provided with light in middle, providing advantages both in terms of touch control and LED lighting evenness and distribution. The resulting configuration is both improved in terms of aesthetics and capacitive touch functionality.

With reference to FIG. 6, the back side of the PCB 46 includes LED connections 94, traces 100, and reverse views of the slider LEDs 56 as shown are arranged in a single row in first portion 98 (corresponding to first portion 60) and in two parallel rows in second portion 96 (corresponding to second portion 62). Various other electric and/or electronic components are also shown and optionally present on the back side of the PCB 46, including optional resistors, capacitors, application-specific integrated circuits (ASICs), and the like. Although not shown, in alternative embodiments the PCB 46 can include holes to allow the light from reverse-mounted LEDs to pass through the PCB 46 to illuminate the control unit 30.

With the above single-PCB configuration, the production of the PCB 46 can be fully automated and have a reduced production cost. Although the PCB 46 is a two-sided board, the operative components will only be on one side (the front side) thereby reducing the manufacturing costs as the PCB does not need to be flipped during manufacture for component placement. The cost of including the copper traces 100 on the rear of PCB 46 as shown is more than offset by the other advantages in the proposed configuration.

The ability for a user to touch the touchscreen control surface 46 and dynamically illuminate the visual indicating LED(s) (e.g., LEDs 56) at substantially the same point as the user's finger with optional push button and slider functionality provides the lowest manufacturing cost, improved touch control and improved light diffusion and aesthetics, by limiting the component placement to one side and providing an improved component stack of the touchscreen controls.

In order to improve the precision of visual indicating LED response to a detected user's touch, multiple LEDs of a single visual touch control region (e.g., slider control 32) can be positioned and can correspond to each touch pad. Various control schemes can utilize various readings at various touch pads to more precisely interpret a user's touch position and light LEDs accordingly. For instance, two or more touch pads (or other touch sensing components or features) nearest a user's finger can receive dynamic readings which can be received at a controller for interpreting position, intensity, and/or movement of the user's finger. False readings can also be reduced by utilizing multiple touch sensors at a time. Based on the precise, composite readings at the touch sensors, multiple display LEDs can light at a time. The control unit 30 and touchscreen surface 36 can light fewer or more LEDs corresponding to each touch sensor location being activated for a finer-grained LED lighting effect that smoothly appears to follow a user's finger. A ratio of multiple LEDs per touch sensor (e.g., 2, 3, etc. LEDs per touch sensor) can provide configurable, smooth, and dynamic lighting that corresponds to smooth readings of the user's touch. By including multiple LEDs per touch pad, circuitry and logic can be provided that causes an illumination of fewer than all LEDs for a particular touch gesture, and the LEDs can be progressively lit based on touch sensing, including touch sensing detected at one or more adjacent or nearby pads. A computer controller with a hardware processor operatively coupled to a memory can be configured to control the selective illumination of the various LEDs in response to a user's touch input.

Various touch and controller logic is contemplated to precisely detect one or more user finger or other detected touch locations along the overall touchscreen of the appliance. For instance, a capacitive effect on one touch pad may be interpreted by the controller to indicate a certain likelihood of a user finger being a certain distance from the touch pad, and a second signal as a second touch pad in combination with the first can provide a more precise location of a user's finger. In some cases, this can therefore permit the controller to utilize a more conventional, rectangular touch pad configuration and array without a need for a more complex or varied zig-zag or chevron style individual touch pad shape. Although the touch pads shown herein are generally rectangular, it is also contemplated that the touch pads can be zig-zag, chevron, wave, or any other suitable shape in alternative embodiments. The LEDs on the PCB 46 are preferably controlled by a controller that is programmed to drive the LEDs using discrete transistors and discrete shift registers.

In various embodiments herein, a touch signal can be measured and/or detected above and/or below LEDs used for visual indicating and lighting. This feature provides an enhanced continuous look of the slider over a typical spring-based design while optimizing touch control aspects.

Various LEDs discussed herein can also be controlled to provide light at a certain brightness (and/or color) defined by an LED duty cycle, optionally also based on a user's finger position. For example, a preferable duly cycle of 1-4% is contemplated. An even more preferable 2-3% duty cycle for each LED is also contemplated. Generally, selecting a higher percentage duty cycle of an LED would denote a greater brightness or light output of that LED. A 0% duty cycle of an LED can denote an LED that is currently off. Likewise, a 100% duty cycle of an LED can denote an LED that is currently operating at maximum brightness.

An example method of a user using the control unit 30 of the blender 10 is shown in three representative steps in FIGS. 7A-7C, where the user's finger 108 moves across the touchscreen surface 36 during control of the blender 10, shown at various stages.

FIG. 7A shows a first stage 102 of a user touch control of the control unit 30 with the selected level line 35 set at or near a minimum level of the slider control 32, e.g., corresponding to a motor being in the off or low speed setting. The user's finger 108 touches the surface 36 (corresponding panel) near a minimum level indication on the slider control 32, and optionally begins to slide the finger 108 to the side, and the level line 35 follows the user's finger 108 smoothly as it moves. Note that also contemplated herein are “touch” based interactions where no physical touch of the user's finger 108 to a surface 36 is necessary. In some cases, a user's hand merely “hovering” over or proximate the surface 36 can sufficiently provide “touch” based control. Therefore, as shown the user's finger 108 may or may not contact various parts of the slider control 32 as the level line 35 is adjusted, for example.

FIG. 7B shows a second stage 104 of a user touch control of the control unit 30 as the user's finger 108 moves to a middle portion of the slider control 32 and the level line 35 is correspondingly generally centered at an intermediate position, e.g., consistent with an intermediate motor setting.

FIG. 7C shows a third stage 106 of a user touch control of the control unit 30 as the user's finger 108 moves to a maximum or upper portion of the slider control 32 and the level line 35 is generally located at a maximum position, e.g., consistent with a full power motor setting.

The various stages 102, 104, and 106 are representative example snapshots of a user operating the blender 10, and the order, positions, and settings of the blender 10 can be any level or variation as would be input to the slider control 32. The user's finger 108 can operate the move the level line 35 from a higher position to a lower position in various embodiments. As discussed herein, additional touch controls other than slider control 32 are preferably also included on touch surface 36 of the control unit 30. Furthermore, additional slider controls similar to slider control 32 can be incorporated into the example blender 10.

As shown and described herein, blender 10 is one possible representative example of an appliance that can incorporate capacitive touch controls as described herein. In particular, blender 10 is an electrically-powered appliance with touch controls. Although embodiments of electrical appliances described herein use an operative component such as a motor with corresponding motor speed and/or blending settings as parameters to be controlled, any other type of electric or electronic appliance can be controlled using the same control unit and controls as described. For example, a motor speed can be controlled using a controller operatively connected to the touch controls. For example, an input voltage and/or pulse-width modulation (PWM) can be adjusted using the touch controls. Other types of operative components to be controlled, such as heaters, etc. are also contemplated herein.

Other examples of appliances contemplated herein include but are not limited to: multi-cookers, pressure-cookers, air fryers, deep fryers, rice cookers, sous-vide appliances, stove top resistive, induction, or flame-based heaters, griddles, ovens, sandwich grills, toasters, waffle irons, toaster ovens, hair straighteners, hair dryers, heat guns, curling irons, irons and steamers, coffee makers, space heaters, water heaters and boilers, etc. and combinations thereof. Yet further examples of appliances, with motor control or otherwise, contemplated herein include other types of electrical appliances, such as those equipped with electrical motors; these include mixers, food processors, fans, full-size and hand-held vacuum cleaners, sewing machines, electric toothbrushes, power drills, power screwdrivers, impact drills, washers, driers, reciprocating and circular saws, televisions, refrigerators, air-conditioners, etc. and combinations thereof. Other electronic devices are also contemplated, such as laptop computers, smart devices (including Internet-of-things enabled devices), mobile phones, desktop computers, and/or any device with a computer integrated therewith. Those of skill in the art would readily understand that the touchscreen controls disclosed herein apply to any suitable type of appliance or other device, provided certain adjustments and adaptations are made that are covered by this description. Also contemplated are based electronic or electrical devices, such as relays and the like for use in controlling other devices.

The present invention has now been described with reference to several embodiments thereof. The foregoing detailed description and examples have been given for clarity of understanding only. No unnecessary limitations are to be understood therefrom. It will be apparent to those skilled in the art that many changes can be made in the embodiments described without departing from the scope of the invention. The implementations described above and other implementations are within the scope of the following claims.

What is claimed is:

1. A multi-layer touchscreen assembly for an appliance, comprising:
a panel comprising an outer touchscreen surface;
an opaque layer positioned below the touchscreen surface and having at least one transparent area therein defining lighting of at least one visual touch control region;
a printed circuit board positioned below the opaque layer, the printed circuit board comprising a plurality of light-emitting diodes proximate one or more corresponding capacitive touch sensors of a first visual touch control region of the one or more visual touch control regions, and the one or more capacitive touch sensors configured to provide a visual indication of a control aspect of the appliance according to a user's touch input; and
at least one diffusion portion operatively positioned between the opaque layer at a transparent area thereof and the printed circuit board at the first visual touch control region.

2. The touchscreen assembly of claim 1, comprising a plurality of diffusion portions, each corresponding to a different visual touch control region of the touchscreen surface and thus positioned between plural corresponding transparent areas of the opaque layer and additional visual touch control regions of the printed circuit board.

3. The touchscreen assembly of claim 2, wherein the plural diffusion portions are operatively positioned at least partially within shaped openings of a diffusion holder that is also operatively positioned between the opaque layer and the printed circuit board.

4. The touchscreen assembly of claim 3, wherein the plural diffusion portions are connected to one another by connecting runners to position the plural diffusion portions within the shaped openings of the diffusion holder in a similar manner relative to the diffusion holder.

5. The touchscreen assembly of claim 4, wherein the diffusion holder is of a similar thickness as the plural diffusion portions and the connecting runners are thinner than the plural diffusion portions and are positioned within like thickness grooves of the diffusion holder.

6. The touchscreen assembly of claim 1, wherein the plurality of light-emitting diodes is greater in number than the number of corresponding touch sensors.

7. The touchscreen assembly of claim 1, wherein at least one of the combination of a transparent area of the opaque layer, a diffusion portion, and a visual touch control region of the printed circuit board form a slider control that is of greater width from one end thereof to another end thereof.

8. The touchscreen assembly of claim 1, wherein the plurality of light-emitting diodes is located on a same side of the printed circuit board as the corresponding touch sensors.

9. The touchscreen assembly of claim 1, further comprising a second plurality of light-emitted diodes proximate one or more corresponding touch sensors of a second visual touch control region.

10. An appliance, comprising:
an operative component that is controllable according to at least a controllable aspect; and
a multi-layer touchscreen assembly operatively connected to the operative component, the multi-layer touchscreen assembly comprising:
a panel comprising an outer touchscreen surface;
an opaque layer positioned below the touchscreen surface and having at least one transparent area therein defining lighting of at least one visual touch control region;
a printed circuit board positioned below the opaque layer, the printed circuit board comprising a plurality of light-emitting diodes proximate one or more corresponding capacitive touch sensors of a first visual touch control region of the one or more visual touch control regions, and the one or more capacitive touch sensors configured to provide a visual indication of the control aspect of the appliance according to a user's touch input, and
at least one diffusion portion operatively positioned between the opaque layer at a transparent area thereof and the printed circuit board at the first visual touch control region.

11. The appliance of claim 10, wherein the one or more corresponding touch sensors of the first visual touch control region are operatively connected to a controller configured to control the operative component.

12. The appliance of claim 10, wherein the operative component is a motor.

13. The appliance of claim 12, wherein the appliance is a blender.

14. The appliance of claim 10, wherein the operative component is a heating element.

15. The appliance of claim 10, wherein the printed circuit board is the only printed circuit board in the touchscreen assembly.

16. The appliance of claim 10, comprising a plurality of diffusion portions, each corresponding to a different visual touch control region of the touchscreen surface and thus positioned between plural corresponding transparent areas of the opaque layer and additional visual touch control regions of the printed circuit board.

17. The appliance of claim 10, wherein the plural diffusion portions are operatively positioned at least partially within shaped openings of a diffusion holder that is also operatively positioned between the opaque layer and the printed circuit board.

18. The appliance of claim 10, wherein the plurality of light-emitting diodes is located on a same side of the printed circuit board as the corresponding touch sensors.

19. A method of making a touchscreen assembly for use in an appliance, comprising:
providing a printed circuit board comprising a plurality of light-emitting diodes proximate one or more corresponding capacitive touch sensors of a first visual touch control region, the capacitive touch sensors configured to selectively control the appliance according to a user's touch input;
providing a diffusion holder holding at least one diffusion portion located above the first visual touch control region of the printed circuit board;
providing an opaque layer having at least a transparent area above the diffusion holder and diffusion portion; and
providing a touchscreen surface above the opaque layer.

20. The method of claim 16, wherein the diffusion layer and diffusion holder are provided substantially co-planar such that the diffusion holder holds the diffusion layer flush respective to the opaque layer and the printed circuit board.
